(19) United States
(12) Patent Application Publication
(10) Pub. No.: US 2017/0063309 A1
(43) Pub. Date: Mar. 2, 2017

(54) METHODS AND APPARATUS FOR REDUCING TRANSIENT GLITCHES IN AUDIO AMPLIFIERS

(71) Applicant: QUALCOMM Incorporated, San Diego, CA (US)

(72) Inventors: Kshitij YADAV, San Diego, CA (US); Vijayakumar DHANASEKARAN, San Diego, CA (US)

(21) Appl. No.: 15/186,273

(22) Filed: Jun. 17, 2016

Related U.S. Application Data
(60) Provisional application No. 62/210,913, filed on Aug. 27, 2015.

(51) Int. Cl. H03F 1/26; H04B 1/40; H04R 3/00; H03F 3/183; H03F 3/45

(52) U.S. Cl. CPC H03F 1/26; H03F 3/183; H03F 3/45475; H04R 3/007; H04B 1/40; H03F 2200/372; H03F 2200/414

(57) ABSTRACT

An audio amplifier, including: at least a two stage amplifier configured to receive an input signal and output an amplified output signal, the at least a two stage amplifier including at least one stage amplifier and an output stage amplifier; and an auxiliary stage amplifier having an input coupled to an output of the at least one stage amplifier and an input of the output stage amplifier.

### CROSS-REFERENCE TO RELATED APPLICATIONS

This application claims the benefit of priority under 35 U.S.C. §119(e) of co-pending U.S. Provisional Patent Application No. 62/210,913, filed Aug. 27, 2015, entitled “Reducing Transient Glitches in Audio Amplifiers.”

### BACKGROUND

Field

This disclosure relates generally to an audio amplifier, and more specifically, to reducing transient glitches in the audio amplifier when it is powered up or powered down.

Background

When a differential audio amplifier turns ON or OFF, transient glitches may couple to the headphone input through the external amplifier. For example, audible pop and click noise can be caused in audio output signals due to transient signals that are generated within the audio output circuitry during this power-up of the audio output circuitry. Similarly, audible pop and click noise can also be generated during power-down of the audio output circuitry. This audible pop and click noise is undesirable, as it can degrade the user experience associated with an audio device that is utilizing the audio output circuitry.

### SUMMARY

The present disclosure describes various implementations of devices and methods for reducing transient glitches such as pop and click noise using an auxiliary stage in a differential audio amplifier.

In one embodiment, an audio amplifier is disclosed. The amplifier includes: at least a two stage amplifier configured to receive an input signal and output an amplified output signal, the at least a two stage amplifier including at least one stage amplifier and an output stage amplifier; and an auxiliary output stage amplifier having an input coupled to an output of the at least one stage amplifier and an input of the output stage amplifier.

In another embodiment, a device is disclosed. The device includes: an antenna configured to transmit and receive RF signal; a radio frequency (RF) transceiver unit coupled to the antenna; a baseband processor coupled to the RF transceiver unit and configured to convert between a voice/data signal and a baseband signal; and an audio codec unit coupled to the baseband processor, the audio codec unit including: at least a two stage amplifier configured to receive an input signal and output an amplified output signal, the at least a two stage amplifier including at least one stage amplifier and an output stage amplifier; and an auxiliary stage amplifier having an input coupled to an output of the at least one stage amplifier and an input of the output stage amplifier. Also included in the implementation is a pull down stage at the output of the output stage amplifier.

In yet another embodiment, a method for reducing transient glitches in an audio amplifier during power up and power down sequence is disclosed. The method includes: enabling at least one stage amplifier and an auxiliary stage amplifier for a period prior to enabling an output stage amplifier, the auxiliary stage amplifier having an input coupled to an output of one of the at least one stage amplifier and an input of the output stage amplifier; and enabling the output stage amplifier while disabling the auxiliary stage amplifier after the period. Also included in the implementation is turning on or turning off of the pull-down switch, wherein the switch is off when the output stage amplifier is on and the switch is on when the output stage amplifier is off.

Other features and advantages of the present disclosure should be apparent from the present description which illustrates, by way of example, aspects of the disclosure.

### BRIEF DESCRIPTION OF THE DRAWINGS

The details of the present disclosure, both as to its structure and operation, may be gleaned in part by study of the appended further drawings, in which like reference numerals refer to like parts, and in which:

FIG. 1 is an exemplary wireless device communicating with a wireless communication system;

FIG. 2 is a functional block diagram of an exemplary design of a wireless device that is one embodiment of the wireless device shown in FIG. 1;

FIG. 3 is a detailed diagram of the audio codec shown in FIG. 2 in accordance with one embodiment of the present disclosure;

FIG. 4 is a functional block diagram of an audio power amplifier that is one embodiment of the audio power amplifier shown in FIG. 3;

FIG. 5 shows timing diagrams of the audio power amplifier in accordance with one embodiment of the present disclosure;

FIG. 6 shows the audio power amplifier with elements that are enabled during the auxiliary stage stabilization period highlighted in bold;

FIG. 7 shows the audio power amplifier with elements that are enabled during the output stage period highlighted in bold;

FIG. 8 is a diagram of an audio codec circuit that is one embodiment of the audio codec of FIG. 2 or FIG. 3, which includes a rear digital-to-analog converter (RDAC);

FIG. 9 shows the audio power amplifier with elements that are enabled during the auxiliary stage stabilization period highlighted in bold;

FIG. 10 shows the audio power amplifier with elements that are enabled during the output stage period highlighted in bold;

FIG. 11 is a flow diagram of a process for reducing transient glitches in an audio amplifier during power up. and

FIG. 12 is a flow diagram of a process to reduce transient glitches during the power down sequence.

### DETAILED DESCRIPTION

As stated above, when a differential audio amplifier turns ON or OFF, transient glitches may couple to the headphone input through the external amplifier. Embodiments as described herein provide for reducing the transient glitches such as pop and click noise using an auxiliary stage in the differential audio amplifier.

After reading this description it will become apparent how to implement the disclosure in various implementations and applications. Although various implementations of the present disclosure will be described herein, it is understood that these implementations are presented by way of example only, and not limitation. As such, this detailed description of various implementations should not be construed to limit the scope or breadth of the present disclosure.

The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

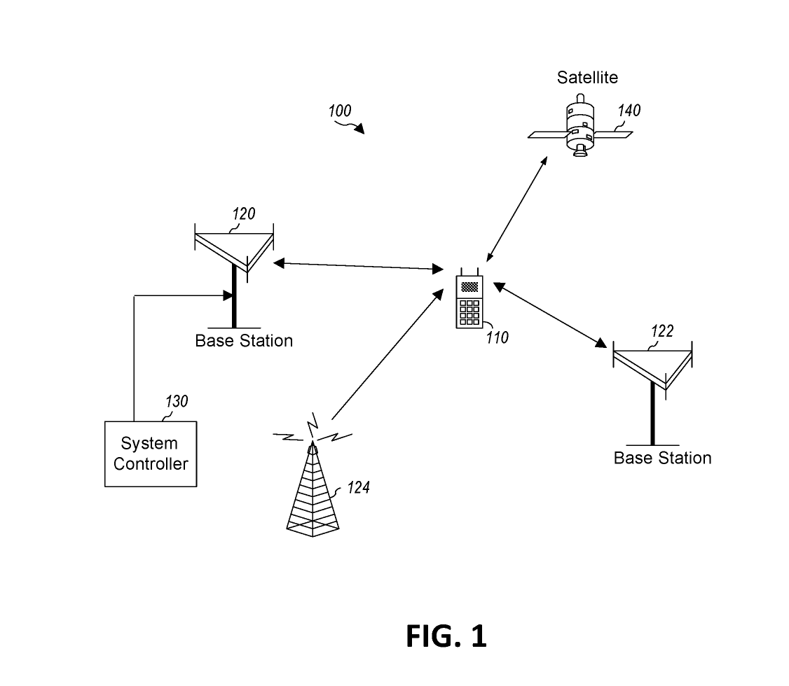

FIG. 1 is an exemplary wireless device 110 communicating with a wireless communication system 100. Wireless communication system 100 may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 100 including two base stations 120 and 122 and one system controller 130. In general, a wireless system may include any number of base stations and any set of network entities.

Wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. Wireless device 110 may communicate with wireless system 100. Wireless device 110 may also receive signals from broadcast stations (e.g., broadcast station 124), signals from satellites (e.g., satellite 140) in one or more global navigation satellite systems (GNSS), etc. Wireless device 110 may support one or more radio technologies for wireless communication including LTE, WCDMA, CDMA 1X, EVDO, TD-SCDMA, GSM, 802.11, etc.

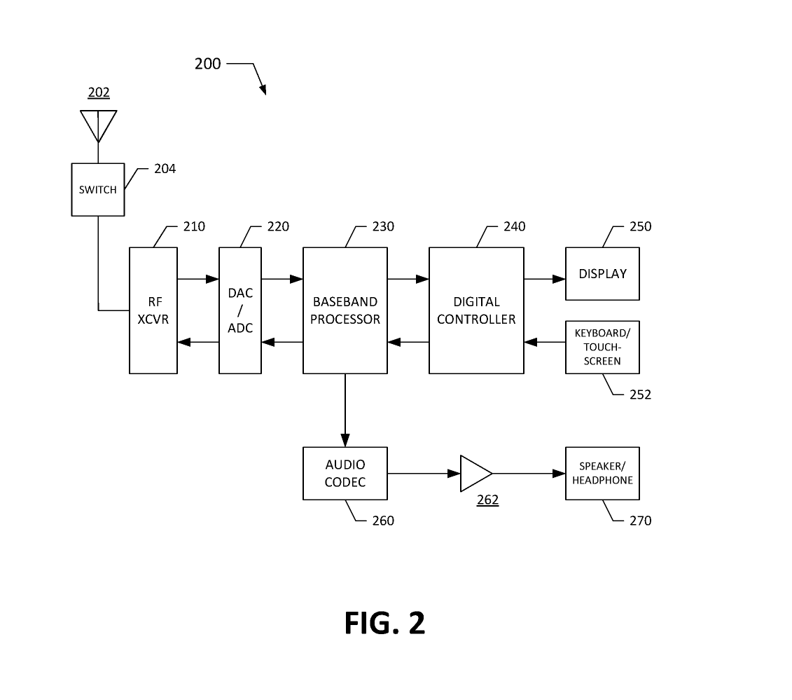

FIG. 2 is a functional block diagram of an exemplary design of a wireless device 200 that is one embodiment of the wireless device 110 of FIG. 1. In this exemplary design, the wireless device 200 includes an antenna 202, a switch 204, a radio frequency (RF) transceiver unit 210, a digital-to-analog converter (DAC)/analog-to-digital converter (ADC) 220, a baseband processor 230, a digital controller 240, a display unit 250, and a keyboard/touch screen 252. The wireless device 200 may also include an audio codec 260 having an audio amplifier, an external amplifier 262, and a speaker/headphone 270. The wireless device 200 may further include other units (not shown) including a universal serial bus unit (USB), a camera, a wireless network interface unit, a subscriber identity module (SIM) card, a battery, memory unit, etc. It should be noted that not all blocks of the wireless device in FIG. 2 are necessary. For example, the DAC/ADC 220 can be subsumed within the baseband processor 230. In another example, the external amplifier 262 may be removed from some configurations.

The RF transceiver unit 210 includes two circuits, a transmitter and a receiver. A wireless device 200 uses the transmitter and the receiver to communicate with other wireless devices. The transmitter transmits radio signals and the receiver receives the radio signals. The transmitter includes, among other units, an RF up converter that converts modulated baseband signal (I and Q) either at zero Intermediate frequency (IF) or some IF to RF frequency. The receiver includes, among other units, an RF down converter that converts RF signal to baseband signal (I and Q). The basic component used for frequency conversion is an RF mixer.

The antenna 202 is a metallic object which converts electro-magnetic signal to electric signal and vice versa. Commonly used antennas in the wireless device are of various types such as helix type, planar inverted type, whip or patch type. Micro-strip based patch type of antennas are often used in mobile devices/phones due to its size, easy integration on the PCB, and multi-frequency band of operation. Since only one antenna is used for both transmit (Tx) and receive (Rx) paths at different times, a Tx/Rx switch 204 is used to connect both the Tx path and the Rx path with the antenna 202 at different times. For a frequency division duplex (FDD) system, a diplexer is used in place of the switch which acts as filter to separate various frequency bands.

The DAC/ADC 220 may be used to convert the analog speech signal to the digital signal and vice versa in the wireless device 200. In the Tx path, the converted digital signal is sent to the speech coder such as an audio codec. The types of ADCs include sigma delta, flash, dual slope, and successive approximation. In the Rx path, the automatic gain control (AGC) and the automatic frequency control (AFC) are used to control gain and frequency. The AGC controls proper maintenance of the DAC by keeping the signal within the dynamic range of the DAC. The AFC controls receiver performance by maintaining the frequency error within a limit.

The baseband processor 230 may convert voice/data to I/Q baseband signal. The baseband processor 230 is sometimes referred to as a physical layer (or Layer 1). The baseband processor 230 may add redundant bits to enable error detection (e.g., using cyclic redundancy check (CRC)) and error correction using forward error correction techniques (e.g., a convolutional encoder (used in the Tx path) and a Viterbi decoder (used in the Rx path). The baseband processor 230 may also perform power management and distribution functions.

The audio codec 260 may be used to compress and decompress the signals to match the data rate to the frame. The audio codec 260 may convert the speech signal at 8 KHz sampling rate to 13 kilobits per second (kbps) rate for a full rate speech traffic channel. The audio codec 260 may couple to the speaker and/or headphone 270 through the external amplifier 262.

The digital controller 240 may control data input and output signals such as switching and driving applications, commands, memory accesses, and executions of programs. The digital controller 240 may also interpret and execute commands to and from the user interface including the display unit 250, the keyboard/touchscreen 252, etc. The digital controller 240 may further manage and execute various applications in an application layer (Layer 7). Applications may include audio, video and image/graphics applications.

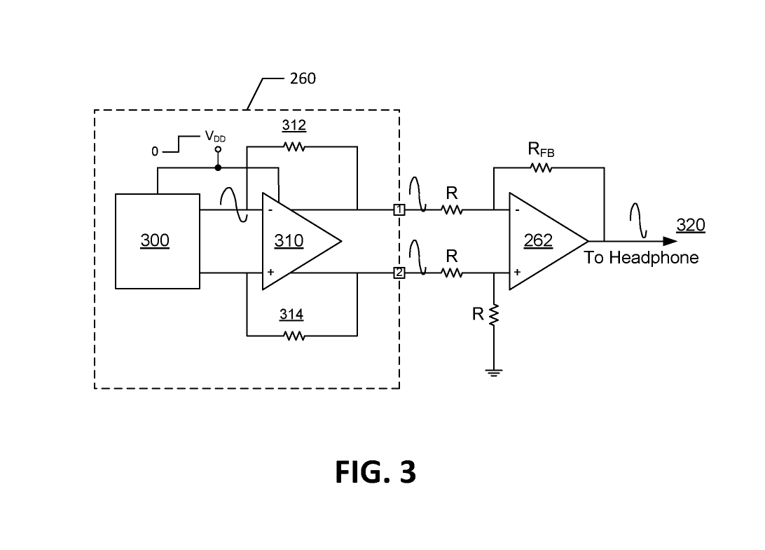

FIG. 3 is a detailed diagram of the audio codec 260 coupled to the external amplifier 262 in accordance with one embodiment of the present disclosure. In the illustrated embodiment of FIG. 3, the audio codec 260 includes a rear digital-to-analog converter (RDAC) 300 and an audio power amplifier 310. The common-mode loop bandwidths of the power amplifier 310 may be less than the outer differential loop bandwidth which can cause any common mode glitch to show up at the differential line-out (LO) output (1, 2), as shown in FIG. 3. The output (1, 2) may couple to the headphone input 320 through the external amplifier 262 to cause transient glitches. Accordingly, embodiments of the present disclosure add an auxiliary stage in the audio power amplifier 310 to reduce the transient glitches such as pop and click noise.

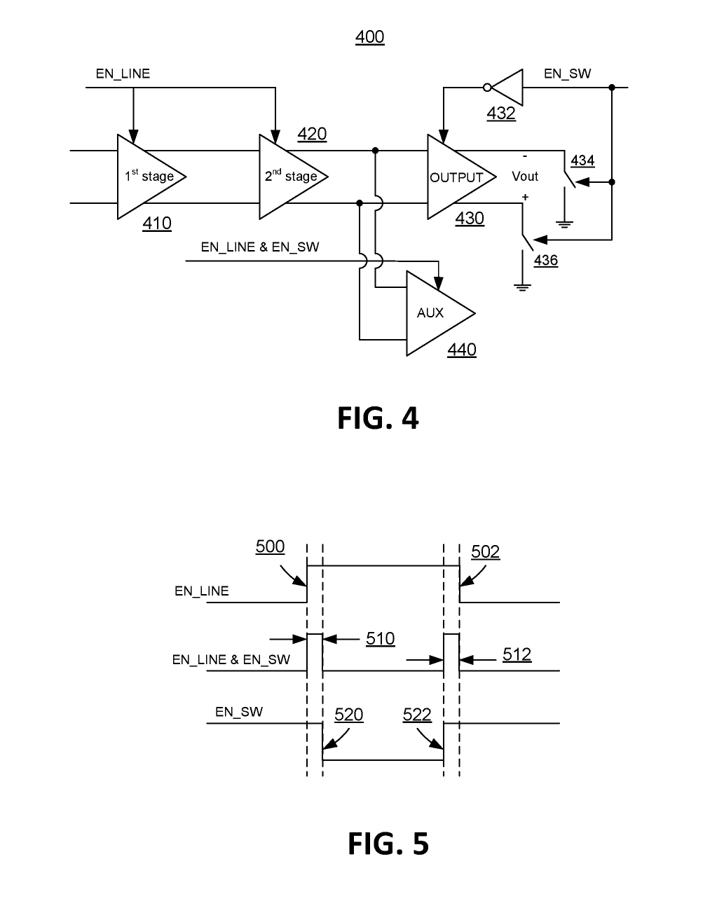

FIG. 4 is a functional block diagram of an audio power amplifier 400 that is one embodiment of the audio power amplifier 310 of FIG. 3. In the illustrated embodiment of FIG. 4, the audio power amplifier 400 is configured as a three-stage amplifier structure including a first stage amplifier 410, a second stage amplifier 420, and an output (or third) stage amplifier 430. It should be noted that the audio power amplifier 400 can be configured to be more than or less than three-stages. The audio power amplifier 400 also includes an auxiliary stage amplifier 440 which is configured to reduce the transient glitches. The techniques described below can be used to stabilize the audio power amplifier 400 when the auxiliary stage amplifier 440 is operational.

In the illustrated embodiment of FIG. 4, a power up sequence includes turning ON the first two stage amplifiers 410, 420 by enabling the line control signal (EN LINE) and turning OFF the output stage amplifier 430 by feeding the enable switch control signal (EN_SW) through an inverter 432. The EN_SW signal also closes switches 434 and 436 to ground the differential output voltage (Vₒᵤₜ), when the output stage amplifier 430 is powered down. The power up sequence also includes turning ON the auxiliary stage amplifier 440 using a combination of EN_LINE and EN_SW signals. In one embodiment, the combination of EN_LINE and EN_SW signals is configured with a logic AND gate. For example, inputs to the AND gate would be EN_LINE and EN_SW signals, while an output provides the combination signal used to turn ON the auxiliary stage amplifier 440.

The auxiliary stage amplifier 440 is turned ON for the duration sufficient to stabilize the nodes of amplifier stages 410 and 420. In one embodiment, the turn-on duration of the auxiliary stage amplifier 440 during the power up/down sequence is in the range between 400 and 600 μs. In another embodiment, the turn-on duration of the auxiliary stage amplifier 440 during the power up/down sequence is in the range of a few microseconds.

In the illustrated embodiment of FIG. 4, a power down sequence includes turning OFF the output stage amplifier 430 by feeding the enabled EN_SW signal through the inverter 432. The EN_SW signal also grounds the differential output voltage (Vₒᵤₜ) with switches 434 and 436. The enabled EN_SW signal also turns ON the auxiliary stage amplifier 440 for a pre-determined duration sufficient to stabilize the nodes of the first two stage amplifiers 410, 420 close to the nominal voltage levels during the power down sequence. Once the nodes of the first two stage amplifiers 410, 420 have stabilized close to the nominal voltage levels, the first two stage amplifiers 410, 420 and the auxiliary stage amplifier 440 are turned OFF by disabling the EN_LINE signal as well.

FIG. 5 shows timing diagrams of an audio power amplifier 400 in accordance with one embodiment of the present disclosure. As described, in the power up sequence, the EN_LINE signal is initially enabled (see transition 500) to turn ON the first two stage amplifiers 410, 420. The EN_SW signal is also enabled to turn ON the auxiliary stage amplifier 440 for a pre-determined duration (see pulse 510). Enabling the EN_SW signal also disables the output stage amplifier 430 and switches 434 and 436 to ground the differential output voltage (Vₒᵤₜ). Once the nodes of the first two stage amplifiers 410, 420 have stabilized close to the nominal voltage levels, the output stage amplifier 430 is turned ON (see transition 520) by feeding the disabled EN_SW signal through the inverter 432.

In the power down sequence, the output stage amplifier 430 is turned OFF (see transition 522) by feeding the enabled EN_SW signal through the inverter 432. The EN_SW signal also grounds the differential output voltage (Vₒᵤₜ) with switches 434 and 436. The enabled EN_SW signal also turns ON the auxiliary stage amplifier 440 for a pre-determined duration (see pulse 512) sufficient to stabilize the nodes of the first two stage amplifiers 410, 420 close to the nominal voltage levels during the power down sequence. Once the nodes of the first two stage amplifiers 410, 420 have stabilized close to the nominal voltage levels, the first two stage amplifiers 410, 420 and the auxiliary stage amplifier 440 are turned OFF by disabling the EN LINE signal as well (see transition 502).

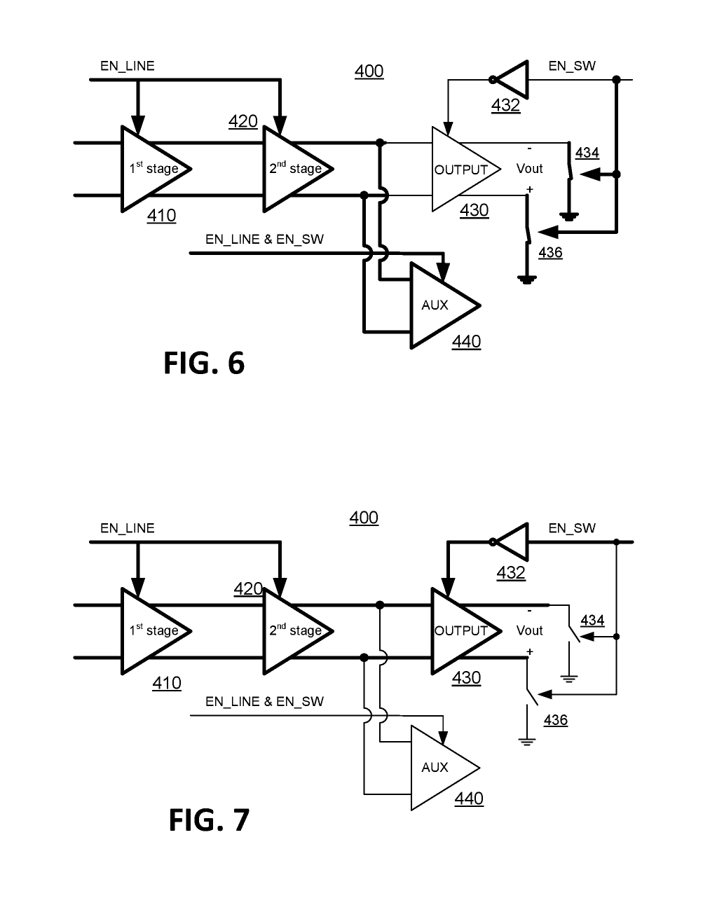

FIG. 6 shows the audio power amplifier 400 with elements that are enabled during the auxiliary stage stabilization period highlighted in bold. As described, the first two stage amplifiers 410, 420, the auxiliary stage amplifier 440, and two switches 434, 436 are enabled (marked in bold) during the auxiliary stage stabilization period, while the output stage amplifier 430 is disabled.

Once the nodes of the first two stage amplifiers 410, 420 have stabilized close to the nominal voltage levels, the output stage amplifier 430 is turned ON by feeding the disabled EN_SW signal through the inverter 432. Disabling the EN_SW signal also turns OFF the auxiliary stage amplifier 440 and opens/disables switches 434 and 436 to provide the differential output voltage (Vₒᵤₜ).

FIG. 7 shows the audio power amplifier 400 with elements that are enabled during the output stage period highlighted in bold. As described, the first two stage amplifiers 410, 420, and the output stage amplifier 430 are enabled (marked in bold) during the output stage period, while the auxiliary stage amplifier 440 and two switches 434, 436 are disabled.

A power down sequence is similar to the power up sequence, but in reverse. Feeding the enabled EN_SW signal through the inverter 432 turns OFF the output stage amplifier 430 and grounds the differential output voltage (Vₒᵤₜ) with switches 434 and 436. The enabled EN_SW signal also turns ON the auxiliary stage amplifier 440 for the duration sufficient to stabilize the nodes of the audio power amplifier 400 during the power down sequence. In one embodiment, the turn-on duration of the auxiliary stage amplifier 440 during the power down sequence is in the range between 400 and 600 μs. In another embodiment, the turn-on duration of the auxiliary stage amplifier 440 during the power up/down sequence is in the range of a few microseconds. In a further embodiment, the turn-on duration of the auxiliary stage amplifier 440 during the power down sequence is different from the turn-on duration of the power up sequence. Once the nodes of the first two stage amplifiers 410, 420 have stabilized close to the nominal voltage levels, the first two stage amplifiers 410, 420 and the auxiliary stage amplifier 440 are turned OFF by disabling the EN LINE signal as well. Accordingly, the turn-on/turn-off durations of the auxiliary stage amplifier 440 provided for voltage stabilization reduces the transient glitches at the output of the audio power amplifier 400. However, other factors such as techniques used to stabilize the audio power amplifier 400 when the auxiliary stage amplifier 440 is operational also reduces the transient glitches at the output of the audio power amplifier 400.

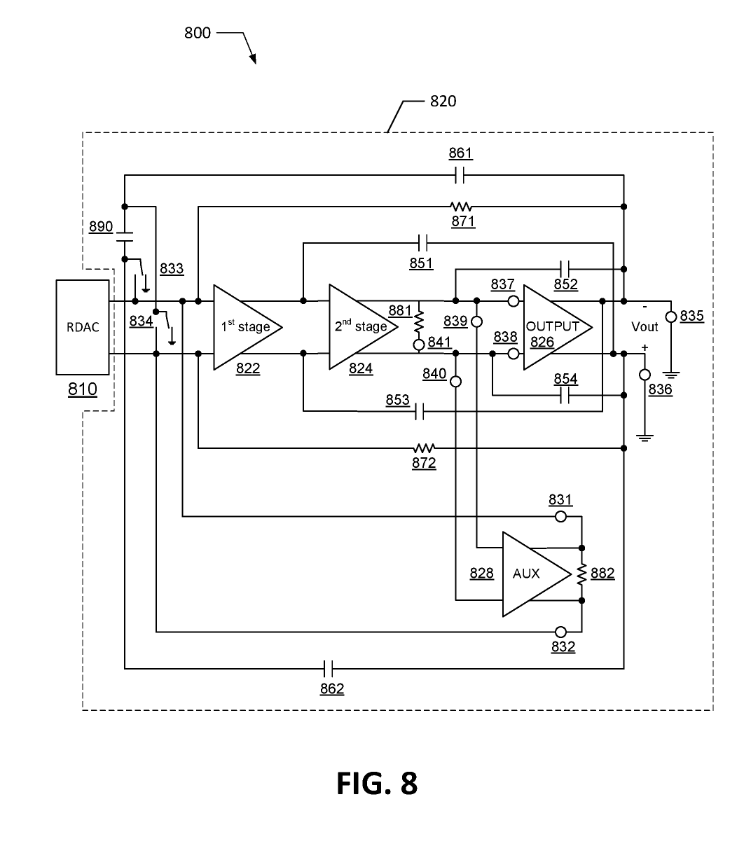

FIG. 8 is a detailed diagram of an audio codec circuit 800 that is one embodiment of the audio codec 260 of FIG. 2 or FIG. 3, which includes an RDAC 810. The remainder of the audio codec circuit 800 is a schematic diagram of an audio power amplifier 820 that is one embodiment of the audio power amplifier 310 (and resistors 312, 314) of FIG. 3. In the illustrated embodiment of FIG. 8, the audio power amplifier 820 is configured as a three-stage amplifier structure including a first stage amplifier 822, a second stage amplifier 824, and an output stage amplifier 826. The audio power amplifier 820 also includes an auxiliary stage amplifier 828 which is configured to reduce the transient glitch. Switches 831 through 841 are provided to switch in appropriate elements during the auxiliary stage stabilization period and the output stage period. Capacitors 851, 852, 853, 854, 861, 862, and resistors 871 and 872 are grounded through switches 835 and 836 during the auxiliary stage stabilization period, while they are used as feedback elements during the output stage period. Resistors 881 and 882 are connected at the outputs of the second stage amplifier 824 and the auxiliary stage amplifier 828 and are switched in during the auxiliary stage stabilization period. Capacitor 890 is connected between the virtual grounds of the first stage amplifier 822 during the output stage period to compensate for feedback capacitors 861 and 862. Capacitor 890 is disconnected during the auxiliary stage stabilization period.

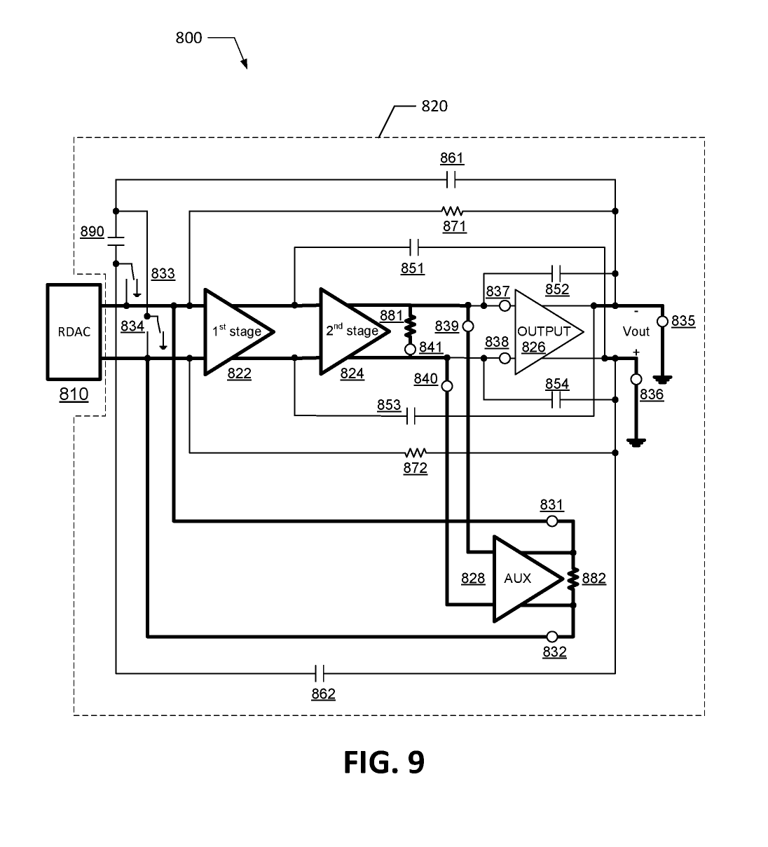

FIG. 9 shows the audio power amplifier 820 with elements that are enabled during the auxiliary stage stabilization period highlighted in bold. As shown, the first two stage amplifiers 822, 824 and the auxiliary stage amplifier 828 are enabled during the auxiliary stage stabilization period. Switches 839 and 840 connect the auxiliary stage amplifier 828, while switches 837 and 838 disconnect the output stage amplifier 826. Resistor 881 (connected through switch 841) provides voltage damping for the output of the second stage amplifier 824, while resistor 882 provides voltage damping for the output of the auxiliary stage amplifier 828. Switches 831 and 832 enable feedback of the output of the auxiliary stage amplifier 828 to the input of the first stage amplifier 822. Switches 835 and 836 ground the output of the audio power amplifier 820 and the feedback resistors 871, 872 and capacitors 851, 852, 853, 854, 861, 862.

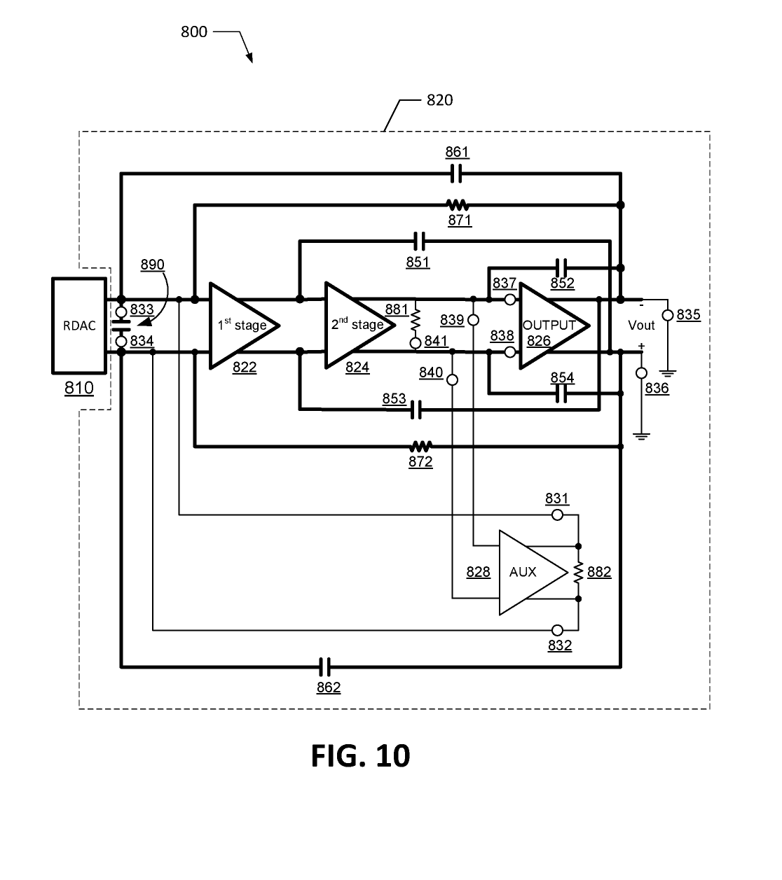

FIG. 10 shows the audio power amplifier 820 with elements that are enabled during the output stage period highlighted in bold. As shown, the first two stage amplifiers 822, 824 and the output stage amplifier 826 are enabled during the output stage period. Capacitors 851 through 854, 861, 862, and resistors 871 and 872 are used as feedback elements during this period. Switches 833 and 834 connect capacitor 890 between the virtual grounds of the first stage amplifier during this period to compensate for feedback capacitors 861 and 862. In some embodiments, to minimize the area overhead of the additional elements in the audio power amplifier (e.g., amplifier 820), the additional elements, including switches, resistors, and auxiliary stage amplifier, are implemented using existing dummy devices in the audio codec.

In alternative embodiments, different configurations are possible depending on the targeted levels of pop and click. For example, embodiments of the present disclosure can be used to target pop and click noises within the range of 20 μV to 100 μV. In an alternative embodiment, embodiments of the present disclosure can be used in conjunction with a dedicated wave-shaping block to target pop and click noises in low levels below 5 μV.

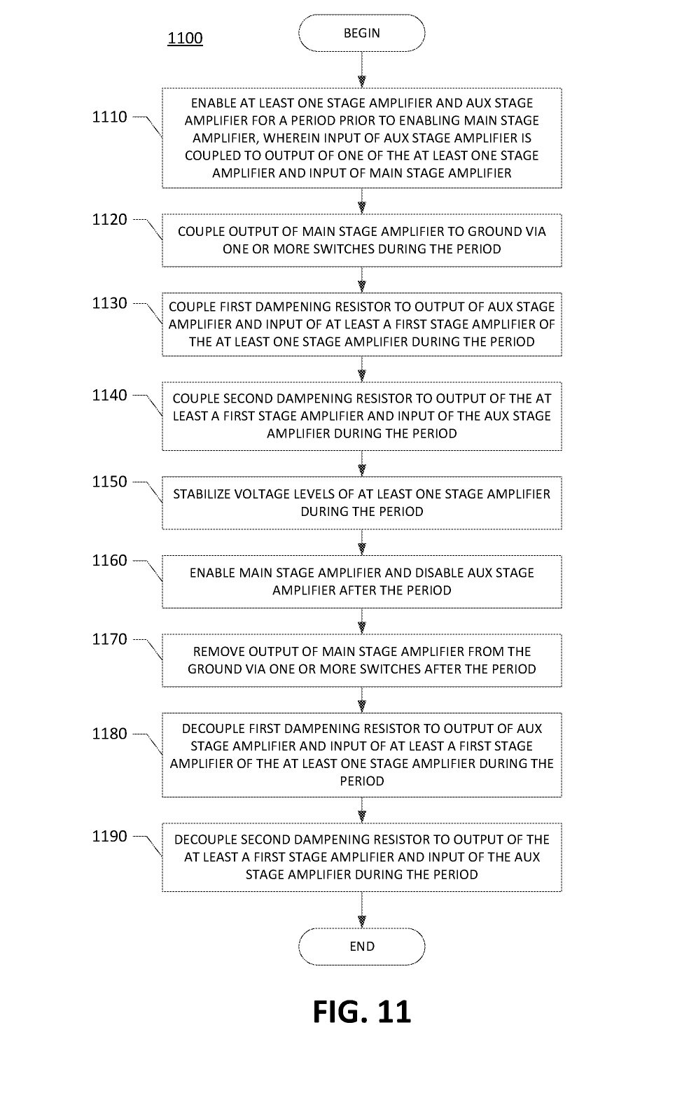

FIG. 11 is a flow diagram of a process 1100 for reducing transient glitches in an audio amplifier during power up sequence in accordance with one embodiment of the present disclosure. In the illustrated embodiment of FIG. 11, at least one stage amplifier and an auxiliary stage amplifier are enabled, at block 1110, for a period prior to enabling an output stage amplifier. The auxiliary stage amplifier has an input coupled to an output of one of the at least one stage amplifier and an input of the output stage amplifier.

In one embodiment, an output of the output stage amplifier is coupled to a ground, at block 1120, via one or more switches during the period. A first dampening resistor is coupled to an output of the auxiliary stage amplifier and an input of at least a first stage amplifier of the at least one stage amplifier during the period, at block 1130. A second dampening resistor is coupled to an output of the at least the first stage amplifier and the input of the auxiliary stage amplifier during the period, at block 1140. Voltage levels of the at least one stage amplifier are then stabilized during the period, at block 1150.

At block 1160, the output stage amplifier is enabled while the auxiliary stage amplifier is disabled after the period. The output of the output stage amplifier is removed from the ground, at block 1170. A first dampening resistor is then decoupled from the output of the auxiliary stage amplifier and the input of at least a first stage amplifier of the at least one stage amplifier during the period, at block 1180. A second dampening resistor is decoupled from the output of the at least the first stage amplifier and the input of the auxiliary stage amplifier during the period, at block 1190.

It should be noted that one or more steps of blocks 1110 to 1150 may performed simultaneously at one time, while one or more steps of blocks 1160 to 1190 may performed simultaneously at another time.

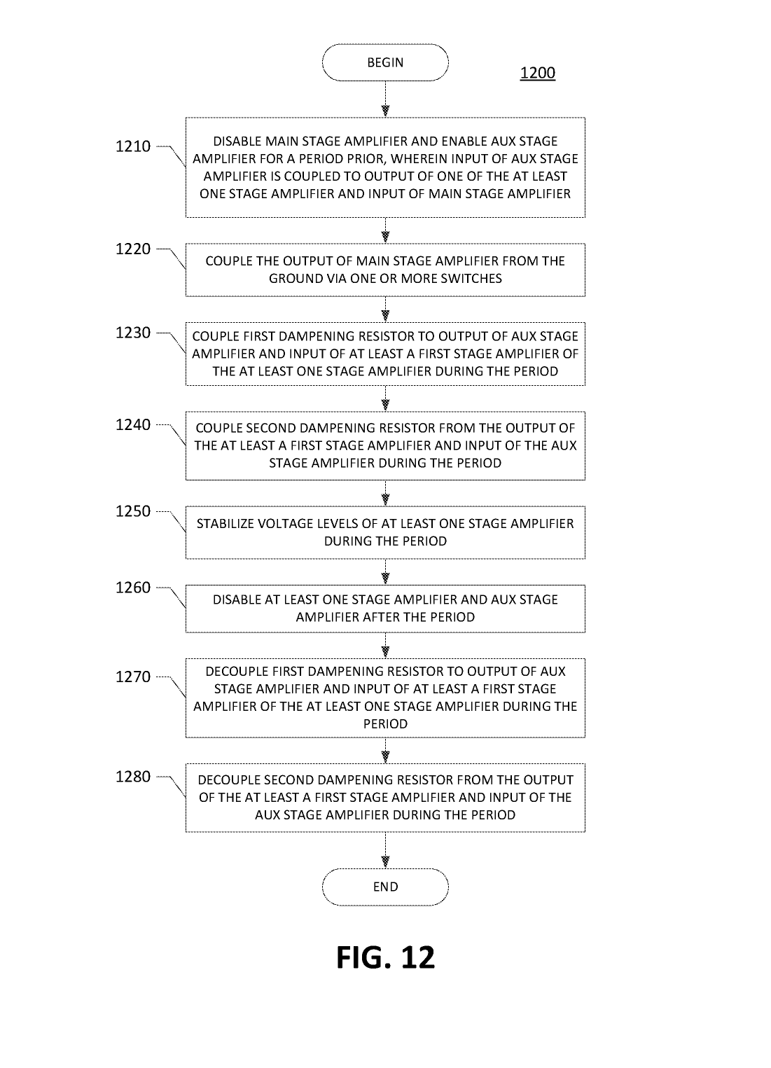

FIG. 12 is a flow diagram of a process 1200 for reducing transient glitches in an audio amplifier during power down sequence in accordance with one embodiment of the present disclosure. In the illustrated embodiment of FIG. 12, the output stage amplifier is disabled while the auxiliary stage amplifier is enabled, at block 1210, for a period prior to disabling the output stage amplifier. The auxiliary stage amplifier has an input coupled to an output of one of the at least one stage amplifier and an input of the output stage amplifier.

In one embodiment, the output of the output stage amplifier is coupled to the ground, at block 1220, via one or more switches during the period. A first dampening resistor is coupled to the output of the auxiliary stage amplifier and the input of at least a first stage amplifier of the at least one stage amplifier during the period, at block 1230. A second dampening resistor is then coupled to the output of the at least the first stage amplifier and the input of the auxiliary stage amplifier during the period, at block 1240. Voltage levels of the at least one stage amplifier are then stabilized during the period, at block 1250.

At block 1260, the at least one stage amplifier and the auxiliary stage amplifier is disabled, after the period. The first dampening resistor is then decoupled from the output of the auxiliary stage amplifier and the input of the at least a first stage amplifier of the at least one stage amplifier during the period, at block 1270. A second dampening resistor is decoupled from the output of the at least the first stage amplifier and the input of the auxiliary stage amplifier during the period, at block 1280.

It should be noted that one or more steps of blocks 1210 to 1250 may performed simultaneously at one time, while one or more steps of blocks 1260 to 1280 may performed simultaneously at another time.

Although several embodiments of the present disclosure are described above, many variations of the present disclosure are possible. For example, although the illustrated embodiments of the present disclosure show only three stages of amplification (e.g., first, second, and output stages or first, second, and auxiliary stages), more or less stages of amplification can be used without departing from the purpose of the configurations as described above. Further, features of the various embodiments may be combined in combinations that differ from those described above. Moreover, for clear and brief description, many descriptions of the systems and methods have been simplified. Many descriptions use terminology and structures of specific standards. However, the disclosed systems and methods are more broadly applicable.

Those of skill will appreciate that the various illustrative blocks and modules described in connection with the embodiments disclosed herein can be implemented in various forms. Some blocks and modules have been described above generally in terms of their functionality. How such functionality is implemented depends upon the design constraints imposed on an overall system. Skilled persons can implement the described functionality in varying ways for each particular application, but such implementation decisions should not be interpreted as causing a departure from the scope of the present disclosure. In addition, the grouping of functions within a module, block, or step is for ease of description. Specific functions or steps can be moved from one module or block without departing from the present disclosure.

The various illustrative logical blocks, units, steps, components, and modules described in connection with the embodiments disclosed herein can be implemented or performed with a processor, such as a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor can be a microprocessor, but in the alternative, the processor can be any processor, controller, microcontroller, or state machine. A processor can also be implemented as a combination of computing devices, for example, a combination of a DSP and a microprocessor, a plurality of microprocessors, one or more microprocessors in conjunction with a DSP core, or any other such configuration. Further, circuits implementing the embodiments and functional blocks and modules described herein can be realized using various transistor types, logic families, and design methodologies.

The above description of the disclosed embodiments is provided to enable any person skilled in the art to make or use the present disclosure. Various modifications to these embodiments will be readily apparent to those skilled in the art, and the generic principles described herein can be applied to other embodiments without departing from the spirit or scope of the present disclosure. Thus, it is to be understood that the description and drawings presented herein represent presently preferred embodiments of the present disclosure and are therefore representative of the subject matter which is broadly contemplated by the present disclosure. It is further understood that the scope of the present disclosure fully encompasses other embodiments that may become obvious to those skilled in the art and that the scope of the present disclosure is accordingly limited by nothing other than the appended claims.

What is claimed is:

1. An audio amplifier, comprising:
at least a two stage amplifier configured to receive an input signal and output an amplified output signal, the at least a two stage amplifier including at least one stage amplifier and an output stage amplifier; and
an auxiliary stage amplifier having an input coupled to an output of the at least one stage amplifier and an input of the output stage amplifier.

2. The audio amplifier of claim 1, further comprising
a first control signal to turn on the at least one stage amplifier and the auxiliary stage amplifier during a period prior to turning on the output stage amplifier.

3. The audio amplifier of claim 2, further comprising
a second control signal to turn on the output stage amplifier and turn off the auxiliary stage amplifier after the period.

4. The audio amplifier of claim 1, further comprising
a first dampening resistor coupled to outputs of the auxiliary stage amplifier and inputs of the at least one stage amplifier.

5. The audio amplifier of claim 4, further comprising
a second dampening resistor coupled to outputs of the at least one stage amplifier and inputs of the auxiliary stage amplifier.

6. The audio amplifier of claim 1, further comprising
a first plurality of feedback capacitors coupled between outputs of the output stage amplifier and inputs of the output stage amplifier.

7. The audio amplifier of claim 6, further comprising
a second plurality of feedback capacitors cross coupled between the outputs of the output stage amplifier and inputs of the at least one stage amplifier.

8. The audio amplifier of claim 7, wherein the at least one stage amplifier comprises a first stage amplifier and a second stage amplifier, and further comprising
a third plurality of feedback capacitors cross coupled between the outputs of the output stage amplifier and inputs of the second stage amplifier.

9. The audio amplifier of claim 8, further comprising
an input capacitor coupled between inputs of the first stage amplifier to compensate for the second plurality of feedback capacitors when the output stage amplifier is turned on, and the input capacitor is disconnected when the output stage amplifier is turned off.

10. The audio amplifier of claim 1, further comprising
a plurality of feedback resistors coupled between outputs of the output stage amplifier and inputs of the at least one stage amplifier.

11. The audio amplifier of claim 1, wherein the auxiliary stage amplifier is configured to reduce transient glitches in the at least one stage amplifier.

12. The audio amplifier of claim 11, wherein the transient glitches include pop and click noises, wherein voltage levels of the pop and click noises are between 20 μV and 100 μV.

13. The audio amplifier of claim 11, wherein voltage levels of the transient glitches are less than 5 μV.

14. A device, comprising:
an antenna configured to transmit and receive RF signal;
a radio frequency (RF) transceiver unit coupled to the antenna;
a baseband processor coupled to the RF transceiver unit and configured to convert between a voice/data signal and a baseband signal; and
an audio codec unit coupled to the baseband processor, the audio codec unit including:
at least a two stage amplifier configured to receive an input signal and output an amplified output signal, the at least a two stage amplifier including at least one stage amplifier and an output stage amplifier; and
an auxiliary stage amplifier having an input coupled to an output of the at least one stage amplifier and an input of the output stage amplifier.

15. The device of claim 14, wherein the audio codec unit further comprises a first control signal to turn on the at least one stage amplifier and the auxiliary stage amplifier during a period prior to turning on the output stage amplifier.

16. The device of claim 15, wherein the audio codec unit further comprises
a second control signal to turn on the output stage amplifier and turn off the auxiliary stage amplifier after the period.

17. The device of claim 14, wherein the audio codec unit further comprises
a first dampening resistor coupled to outputs of the auxiliary stage amplifier and inputs of the at least one stage amplifier.

18. The device of claim 17, wherein the audio codec unit further comprises
a second dampening resistor coupled to outputs of the at least one stage amplifier and inputs of the auxiliary stage amplifier.

19. The device of claim 14, wherein the audio codec unit further comprises
a first plurality of feedback capacitors coupled between outputs of the output stage amplifier and inputs of the output stage amplifier.

20. The device of claim 19, wherein the audio codec unit further comprises
a second plurality of feedback capacitors cross coupled between the outputs of the output stage amplifier and inputs of the at least one stage amplifier.

21. The device of claim 20, wherein the at least one stage amplifier of the audio codec unit comprises a first stage amplifier and a second stage amplifier, the audio codec unit further comprising
a third plurality of feedback capacitors cross coupled between the outputs of the output stage amplifier and inputs of the second stage amplifier.

22. The device of claim 21, wherein the audio codec unit further comprises
an input capacitor coupled between inputs of the first stage amplifier to compensate for the second plurality of feedback capacitors when the output stage amplifier is turned on, and the input capacitor is disconnected when the output stage amplifier is turned off.

23. The device of claim 14, wherein the audio codec unit further comprises
a plurality of feedback resistors coupled between outputs of the output stage amplifier and inputs of the at least one stage amplifier.

24. A method for reducing transient glitches in an audio amplifier during power up and power down sequence, the method comprising:
enabling at least one stage amplifier and an auxiliary stage amplifier for a period prior to enabling an output stage amplifier, the auxiliary stage amplifier having an input coupled to an output of one of the at least one stage amplifier and an input of the output stage amplifier; and
enabling the output stage amplifier while disabling the auxiliary stage amplifier after the period.

25. The method of claim 24, further comprising
grounding an output of the output stage amplifier to a ground via one or more switches during the period.

26. The method of claim 25, further comprising
removing the output of the output stage amplifier from the ground via the one or more switches after the period.

27. The method of claim 24, further comprising
stabilizing voltage levels of the at least one stage amplifier during the period.

28. The method of claim 24, further comprising
coupling a first dampening resistor to an output of the auxiliary stage amplifier and an input of at least a first stage amplifier of the at least one stage amplifier during the period.

29. The method of claim 28, further comprising
coupling a second dampening resistor to an output of the at least a first stage amplifier and the input of the auxiliary stage amplifier during the period.
